(19) United States
(12) Patent Application Publication
(10) Pub. No.: US 2026/0212904 A1
(43) Pub. Date: Jul. 23, 2026

(54) HOST-SIDE ALIGNMENT TO A MULTI-PHASE INTERNAL CLOCK OF A MEMORY SYSTEM

(71) Applicant: Micron Technology, Inc., Boise, ID (US)

(72) Inventors: Casto Salobrena Garcia, Munich (DE); Kevin Gajera, Munich (DE)

(21) Appl. No.: 19/427,875

(22) Filed: Dec. 19, 2025

Related U.S. Application Data
(60) Provisional application No. 63/747,858, filed on Jan. 21, 2025.

(51) Int. Cl. G11C 7/22; G11C 7/10

(52) U.S. Cl. CPC G11C 7/222; G11C 7/1048; G11C 7/1066

(57) ABSTRACT

Methods, systems, and devices for host-side alignment to a multi-phase internal clock of a memory system are described. An apparatus may be configured to implement host-side alignment to a multi-phase internal clock of the memory system. Techniques to implement host-side alignment may include a host system issuing a synchronization pattern to the memory system. The memory system may, based on the synchronization pattern, provide a return mapping that indicates a degree of alignment between a clock of the host system and phases of a multi-phase internal clock of the memory system. Based on the indication, the host system may implement a timing offset that synchronizes the host system with the memory system, thereby enabling information that is subsequently transmitted from the host system to be decoded by the memory system.

### CROSS REFERENCE

The present Application for Patent claims priority to U.S. patent application Ser. No. 63/747,858 by Garcia et al., entitled “HOST-SIDE ALIGNMENT TO A MULTI-PHASE INTERNAL CLOCK OF A MEMORY SYSTEM,” filed Jan. 21, 2025, which is assigned to the assignee hereof, and which is expressly incorporated by reference in its entirety herein.

### TECHNICAL FIELD

The following relates to one or more systems for memory, including host-side alignment to a multi-phase internal clock of a memory system.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports host-side alignment to a multi-phase internal clock of a memory system in accordance with examples as disclosed herein.

FIG. 2 shows aspects of an example of an interface training mode that supports host-side alignment to a multi-phase internal clock of a memory system in accordance with examples as described herein.

FIG. 3 shows an example of a sampling operation that supports host-side alignment to a multi-phase internal clock of a memory system in accordance with examples as disclosed herein.

FIG. 4 shows an example of a sampling operation that supports host-side alignment to a multi-phase internal clock of a memory system in accordance with examples as disclosed herein.

FIG. 5 shows an example of a sampling operation that supports host-side alignment to a multi-phase internal clock of a memory system in accordance with examples as disclosed herein.

FIG. 6 shows an example of a sampling operation that supports host-side alignment to a multi-phase internal clock of a memory system in accordance with examples as disclosed herein.

FIG. 7 shows a block diagram of an apparatus that supports host-side alignment to a multi-phase internal clock of a memory system in accordance with examples as disclosed herein.

FIGS. 8 and 9 show flowcharts illustrating a method or methods that support host-side alignment to a multi-phase internal clock of a memory system in accordance with examples as disclosed herein.

### DETAILED DESCRIPTION

In some cases, an apparatus includes a host system that is in electronic communication with a memory system that includes double data rate (DDR) dynamic random access memory (DRAM). For the memory system to decode information from the host system, timing of signals transmitted from the host system to the memory system may be synchronized with a multi-phase internal clock of the memory system through establishment of a command start point (CSP).

In some systems, techniques to establish the CSP may include using a handshake protocol (e.g., an exchange of dedicated commands and acknowledgments) between the host system and the memory system. The handshake protocol, which relies on use of a command decoder of the memory system, may be performed after command/address bus training of the apparatus. The handshake protocol may span clocking cycles of the multi-phase internal clock plus additional preamble/post amble clocking cycles that are specific to a supplier of the memory system. Use of the handshake protocol may increase a complexity of the command decoder and introduce delays into an initialization process that may reduce a performance of the apparatus.

In accordance with examples as described herein, an apparatus may be configured to implement host-side alignment to a multi-phase internal clock of a memory system. In contrast to using the handshake protocol that establishes a command start point as described above, techniques to implement host-side alignment may include the host system (e.g., a controller of the host system) issuing a synchronization pattern to the memory system. The memory system may, using a burst boundary in combination with the synchronization pattern, provide a return mapping that indicates a degree of alignment between a clock of the host system and phases of a multi-phase internal clock of the memory system. Based on the indication, the host system may implement a timing offset (e.g., a phase shift) that synchronizes the host system with the memory system, thereby enabling information that is subsequently transmitted from the host system to be decoded by the memory system without fewer errors.

The host-side alignment examples described herein may occur as part of command/address bus training of the apparatus and not rely on use of a decoder of the memory system. Such examples may reduce an amount of time needed for synchronization (e.g., not span preamble/post amble clocking cycles that are specific to a supplier of the memory system) and/or reduce an amount of power consumed by the memory system (e.g., not rely on handshake and/or decoding operations), thereby improving an overall performance of the apparatus.

In addition to applicability in memory systems as described herein, techniques for host-side alignment to a multi-phase clock of a memory system may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving memory access speeds, which may decrease processing or latency times, improve response times, or otherwise improve user experience, among other benefits.

Features of the disclosure are illustrated and described in the context of systems and architectures. Features of the disclosure are further illustrated and described in the context of a system including a memory device and a host controller, clocking diagrams related to training a command/address and data bus interface between the memory device and the host controller, and flowcharts.

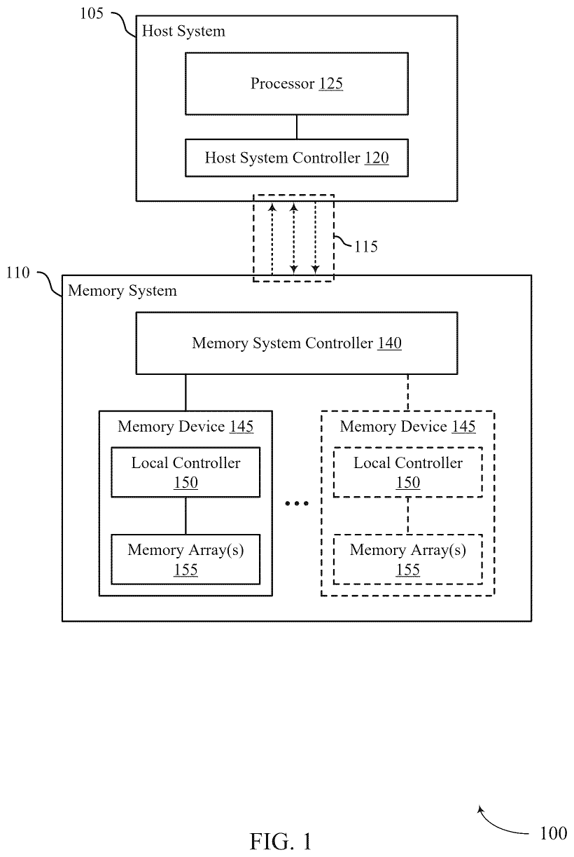

FIG. 1 shows an example of a system 100 that supports host-side alignment to a multi-phase internal clock of a memory system in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

A host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). A processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. A processor 125 may be an example of a central processing unit (CPU), a graphics processing unit (GPU), a general-purpose GPU (GPGPU), or an SoC or a component thereof, among other examples.

A host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating a memory system 110, such as write commands, read commands, configuration signaling or other operational signaling. In some examples, a host system controller 120, or associated functions described herein, may be implemented by or be part of a processor 125. For example, a host system controller 120 may be hardware, instructions (e.g., software, firmware), or a combination thereof implemented by a processor 125 or other component of a host system 105. In various examples, a host system 105 or a host system controller 120 may be referred to as a host.

A memory system 110 provides physical memory locations (e.g., addresses) that may be used or referenced by the system 100. A memory system 110 may include a memory system controller 140 and one or more memory devices 145 (e.g., memory packages, memory dies, portions of a memory die) operable to store data. A memory system 110 may be configurable for operations with different types of host systems 105 and may respond to commands from the host system 105 (e.g., from a host system controller 120). For example, a memory system 110 (e.g., a memory system controller 140) may receive a write command indicating that the memory system 110 is to store data received from a host system 105, or receive a read command indicating that the memory system 110 is to provide data stored in a memory device 145 to a host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of a memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with a host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some examples, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A command/address channel (e.g., a CA channel) may be operable to communicate commands between the host system 105 and the memory system 110, including control information associated with the commands (e.g., address information, configuration information). Commands carried by a command/address channel may include a write command with an address for data to be written to the memory system 110 or a read command with an address of data to be read from the memory system 110.

A clock signal channel may be operable to communicate one or more clock signals between the host system 105 and the memory system 110. Clock signals may oscillate between a high state and a low state, and may support coordination (e.g., in time) between operations of the host system 105 and the memory system 110. In some examples, a clock signal may provide a timing reference for operations of the memory system 110. A clock signal may be referred to as a control clock signal, a command clock signal, or a system clock signal. A system clock signal may be generated by a system clock, which may include one or more hardware components (e.g., oscillators, crystals, logic gates, transistors).

A data channel (e.g., a DQ channel) may be operable to communicate (e.g., bidirectionally) information (e.g., data, control information) between the host system 105 and the memory system 110. For example, a data channel may communicate information from the host system 105 to be written to the memory system 110, or information read from the memory system 110 to the host system 105. In some examples, channels 115 may include one or more error detection code (EDC) channels. An EDC channel may be operable to communicate error detection signals, such as checksums or parity bits, which may accompany information conveyed over a data channel.

Signaling may be communicated over the channels 115 using single data rate (SDR) signaling or double data rate (DDR) signaling, among other rates (e.g., relative to a clock signal). In SDR signaling, one modulation symbol (e.g., signal level) of a signal may be registered for each clock cycle (e.g., on a rising edge or a falling edge of a clock signal). In DDR signaling, two modulation symbols of a signal may be registered for each clock cycle (e.g., on both a rising edge and a falling edge of a clock signal).

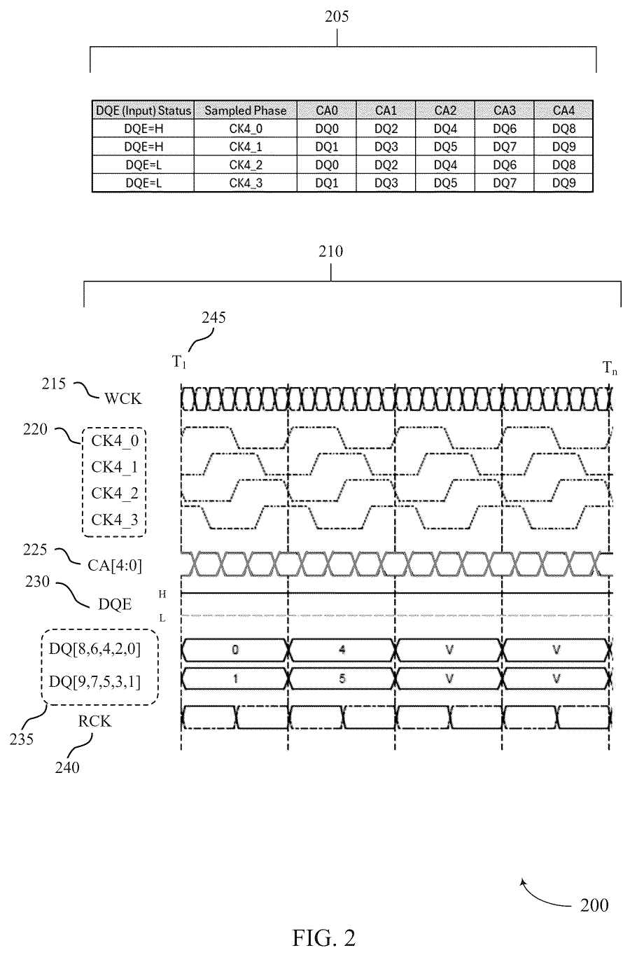

Synchronizing a clock of the host system 105 (e.g., a clock of the host system controller 120) and a clock of the memory system 110 (e.g., a clock of a memory device 145) may enable the memory system 110 to decode information (e.g., commands, data packets) received from the host system 105 without error. In a case where each memory device 145 is a DDR DRAM memory device, and as described in greater detail in connection with FIGS. 2 through 5, synchronizing the host system 105 and the memory system 110 may rely on detecting a degree of alignment of a single-phase clock of the host system controller 120 with a reference phase (e.g., a zero-degree reference phase) of a multi-phase internal clock of the memory system and/or the memory device 145.

In some examples, synchronizing the host system 105 with the memory system 110 may include the memory system 110 entering a command/address bus training mode and the host system controller 120 providing a synchronization pattern to the memory system 110 across CA channels. In some examples, the host controller 120 may provide the synchronization pattern in a burst of commands across the CA channels that spans one or more cycles of the single-phase clock.

In response, the memory system 110 may provide a CA capture to DQ return mapping that indicates a degree of alignment between the single-phase clock and the reference phase. Based on the indication, the host system controller 120 may implement a timing offset (e.g., a phase shift) that synchronizes the host system controller 120 with the memory system 110, thereby enabling the memory system 110 to decode information that is received from the host system controller 120 without fewer errors.

FIG. 2 shows aspects of an example of an interface training mode 200 that supports host-side alignment to a multi-phase internal clock of a memory system in accordance with examples as described herein. The interface training mode 200 may be a CA bus interface training mode that uses a sequence of sampling operations to train CA and DQ bus interfaces of a memory system (e.g., the memory system 110 and/or the memory device 145 of FIG. 1).

The sequence of sampling operations may be performed, at least in part, by an internal bridge of the memory system (e.g., the memory system 110). The internal bridge may include integrated circuitry that determine logical values of data signals at specific points in time (e.g., voltages levels corresponding to a “0” or a “1”, or an “L” and an “H”) received over one or more CA channels and output the information as feedback information over one or more DQ channels. Such integrated circuitry may include input buffers, clocked flip-flops, phase detectors, control logic, and/or other suitable integrated circuitry, among other examples.

Training the CA bus of the memory system may effectuate timings that allow a decoder of the memory system to decode information (e.g., commands, data packets) received from a host system without error. Such timings may include synchronizing transmission of the information (e.g., by the host system controller 120 of FIG. 2) such that receipt of an initial portion of the information (e.g., an initial subpacket) aligns with an internal reference clock of the memory system.

Aspects of the interface training mode 200 include a mapping table 205 (e.g., a CA capture to DQ return mapping) that may be based, at least in part, on a configuration of the internal bridge, where the internal bridge is between command/address inputs (e.g., CA [4:0]) of the memory system and data inputs/outputs (e.g., DQ [9:0]) of the memory system. The mapping table 205 may provide a relationship between the CA inputs, the DQ outputs, and a DQ channel error (DQE) input of the memory system. The mapping table 205 may further provide interrelationships with phases of the multi-phase internal clock that include CK4_0 (e.g., a zero-degree reference phase), CK4_1 (e.g., a phase that is shifted 90-degrees from the zero-degree reference phase), CK4_2 (e.g., a phase that is shifted 180-degrees from the zero-degree reference phase), and CK4_3 (e.g., a phase that is shifted 270-degrees from the zero-degree reference phase). The interrelation may be used to link values received during a time period (e.g., a first UI) via a first command/address line with outputs on a first data line during another time period (e.g., a second unit interval).

FIG. 2 further shows an example clocking diagram 210 that, based on the configuration of the internal bridge, may influence the mapping table 205. In some examples, the clocking diagram 210 includes one or more elements that is used to describe operability of a DDR DRAM memory device.

The clocking diagram 210 includes a single-phase clock 215 and a multi-phase clock 220. In some examples, the single-phase clock 215 is an external write clock (WCK) that the memory system receives from a controller (e.g., the host system controller 120 of FIG. 1). The single-phase clock 215 may be used for clocking data buses and/or command buses between the memory system and the host controller. In some examples, the multi-phase clock 220 is an internal clock that is generated by the memory system. As shown, the multi-phase clock 220 may include the phases CK4_0 through CK4_3.

As further shown in FIG. 2, the clocking diagram 210 includes command/address signal 225. The command/address signal 225 may correspond to sampling windows (e.g., sampling time periods) during which information (e.g., commands, data packets) the memory system receives through command/address inputs CA [4:0] is valid (e.g., stable and capable of being sampled without error).

As further shown in FIG. 2, the clocking diagram 210 includes a DQE input 230 (e.g., an error channel associated with the DQ channel). The DQE input 230 may correspond to a logic state (e.g., a high or low logic state) as referenced in the mapping table 205.

As further shown in FIG. 2, the clocking diagram 210 includes DQ signal 235. The DQ signal 235 may correspond to valid sampling windows (e.g., sampling time periods) during which information (e.g., data packets) the memory system receives or transmits through the data inputs/outputs DQ [9:0] is valid (e.g., stable and capable of being sampled without error). In some examples, and as part of the clocking diagram 210, the DQ signal 235 may segregate group DQ [8, 6, 4, 2, 0] from group DQ [9, 7, 5, 3, 1] to better align and/or translate against the mapping table 205.

As further shown in FIG. 2, the clocking diagram 210 includes a read clock 240. In some examples, the read clock 240 is an internal read clock (RCK) that the memory system provides to the controller.

As further shown in FIG. 2, the clocking diagram 210 includes time periods 245 (e.g., T₁ through Tₙ). Each time period may correspond to a cycle of a phase of the multi-phase clock 220 and serve as a reference for timing considerations during operation of the memory system while the memory system is in a command/address bus training mode.

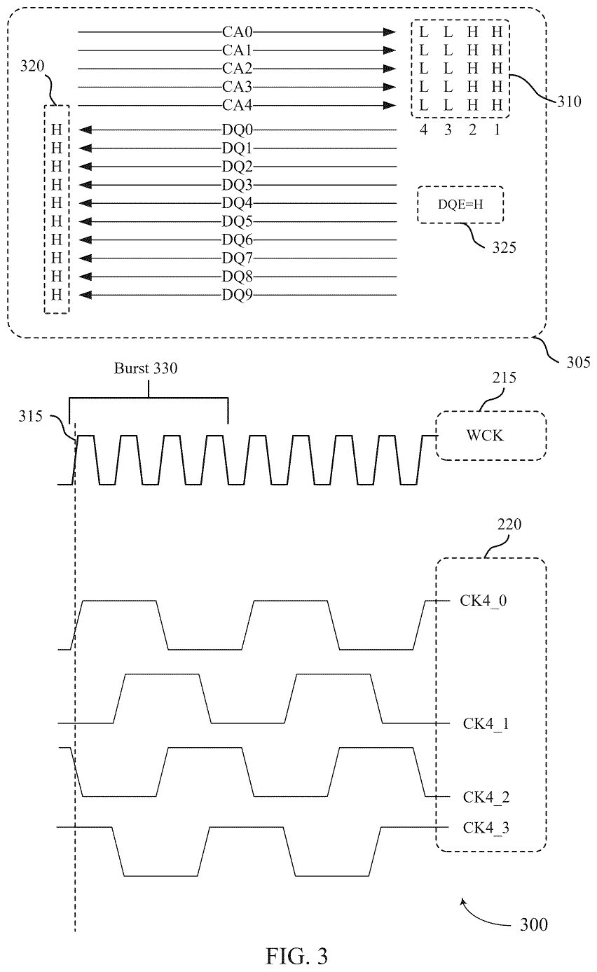

FIG. 3 shows an example of a sampling operation 300 that supports host-side alignment to a multi-phase internal clock of a memory system in accordance with examples as disclosed herein. The sampling operation 300 may be performed, at least in part, by an internal bridge of a memory system using aspects described in connection with FIG. 2 and elsewhere herein. The sampling operation 300 may be performed after the memory system enters a training mode (e.g., a CA bus training mode).

The sampling operation 300 may be configured to align the memory system's (e.g., the DDR DRAM's) internal multi-phase clock (e.g., multi-phase clock 220, an internal CK4 clock of the DDR DRAM) with a burst boundary communicated over the CA lines by the host system. In some systems, the host system may issue commands in a burst 330 of one or more unit intervals (UIs). In some examples, the length of the burst 330 may be four UIs. However, other burst lengths are also possible (e.g., burst lengths of 1 UI, 2 UIs, 3 UIs, 4 UIs, 5 UIs, 6 UIs, 7 UIs, 8 UIs, 9 UIs, 10 UIs, 11 UIs, 12 UIs, 13 UIs, 14 UIs, 15 UIs, 16 UIs). The burst boundary 315 may indicate the start of the burst 330.

A UI may refer to a time duration that is used to transmit one bit of information. In the context of the single-phase clock 215, the UI stretches from a rising edge to the next rising edge of a clock signal. In other examples, a UI may stretch from a falling edge to the next falling edge of a clock signal. In other examples (e.g., DDR DRAM), a UI may stretch from a rising edge to falling edge (or vice-versa) of a clock signal.

The sampling operation 300 enables the host system and the memory system to align the burst boundary 315 of the burst 330 with the correct phase of the multi-phase clock of the memory system. If there is a misalignment between the burst boundary 315 and the multi-phase clock, the memory system may identify more errors in the signal communicated over the CA lines. The sampling operation 300 may occur when the memory system transitions to normal operation (e.g., after exiting a sleep mode, after exiting a refresh mode).

As part of the sampling operation 300, and as shown in the upper portion of FIG. 3, a CA capture to DQ return mapping operation 305 (e.g., performed in accordance with the mapping table 205 and the clocking diagram 210 of FIG. 2) may include the memory system receiving a packet including a synchronization pattern 310. As an example, and as shown in FIG. 3, the synchronization pattern 310 may be an example of a signal communicated over one or more unit intervals (sometimes referred to as UIs). The synchronization pattern 310 may include first HHHHH logic states, followed by second HHHHH logic states, followed by first LLLLL logic states, followed by second LLLLL logic states. Said another way, during a first UI (denoted by ‘1’) HHHHH is sent across the individual lines of the CA channel, during a second unit interval (denoted by ‘2) HHHHH is sent across the individual lines of the CA channel, during a third UI (denoted by ‘3’) LLLLL is sent across the individual lines of the CA channel, and during a fourth UI (denoted by ‘4’) LLLLL is sent across the individual lines of the CA channel. In some examples, the synchronization pattern 310 is received via CA lines (e.g., a command/address bus corresponding to CA [4:0]) between a memory system including the memory system (e.g., the memory system 110) and a host system including a controller (e.g., the host system 105).

As shown in the lower portion of FIG. 3, the sampling operation 300 may further include the memory system receiving, from the host system, the single-phase clock 215. Using the single-phase clock 215, and based on a configuration of the internal bridge, the memory system may identify a degree of alignment between the burst boundary 315 associated with the single-phase clock 215 and a phase of the multi-phase clock 220. As shown in FIG. 3, the degree of alignment corresponds to an edge (e.g., a rising edge or a falling edge) of the single-phase clock 215 being aligned with an edge (e.g., a rising edge or a falling edge) of at least one of the phases of the phase CK4_0 (e.g., a zero-degree reference phase).

Based on the degree of alignment, the memory system may generate a data word 320 that is indicative of a state of synchronization between the single-phase clock 215 and the multi-phase clock 220. As an example, and to indicate the single-phase clock 215 is synchronized (e.g., aligned with phase CK4_0), the data word 320 may include HHHHHHHHHH logic states communicated across DQ [9:0] (e.g., during a single UI). The data word 320 may be based, at least in part, on a logic state 325 of a DQE input during the training (e.g., an H logic state of the DQE input 230 in accordance with the mapping table 205). The data word 320 may then be transmitted to the host system via DQ lines (e.g., a data bus including DQ [9:0]) between the memory system and the host system.

After receiving the data word 320 and based at least in part on the data word 320, the host system may determine that the single-phase clock 215 is aligned with CK4_0 (e.g., the zero-degree reference phase). The host system may further determine that implementing an offset relative to the single-phase clock 215 (e.g., to enable the memory system to decode subsequent transmissions) is equal to zero.

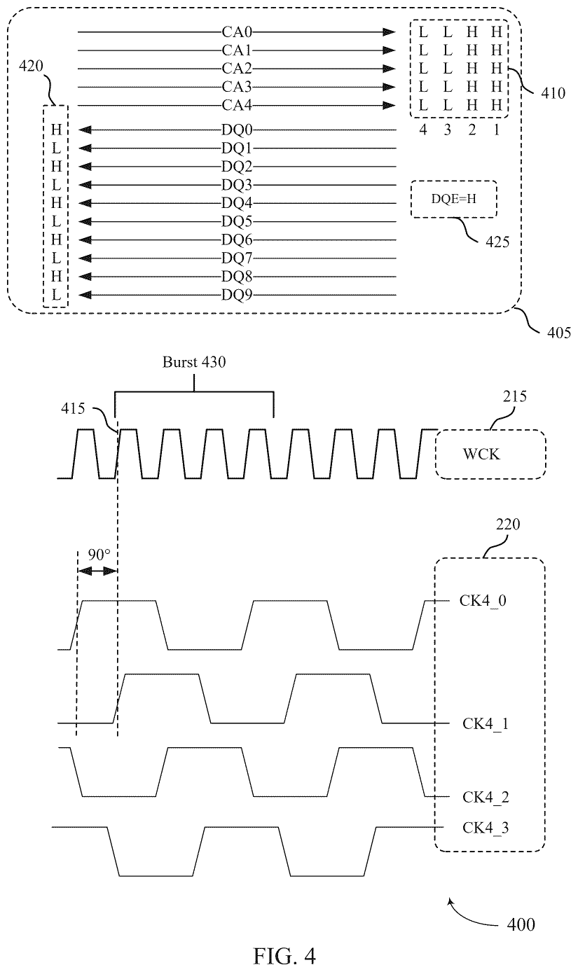

FIG. 4 shows an example of a sampling operation 400 that supports host-side alignment to a multi-phase internal clock of a memory system in accordance with examples as disclosed herein. The sampling operation 400 may be performed, at least in part, by an internal bridge of a memory system using aspects described in connection with FIG. 2 and elsewhere herein. The sampling operation 400 may be performed after the memory system enters a training mode (e.g., a CA bus training mode).

The sampling operation 400 may be configured to align the memory system's (e.g., the DDR DRAM's) internal multi-phase clock (e.g., multi-phase clock 220, an internal CK4 clock of the DDR DRAM) with a burst boundary communicated over the CA lines by the host system. In some systems, the host system may issue commands in a burst 430 of one or more UIs. In some examples, the length of the burst 430 may be four UIs. However, other burst lengths are also possible (e.g., burst lengths of 1 UI, 2 UIs, 3 UIs, 4 UIs, 5 UIs, 6 UIs, 7 UIs, 8 UIs, 9 UIs, 10 UIs, 11 UIs, 12 UIs, 13 UIs, 14 UIs, 15 UIs, 16 UIs). The burst boundary 415 may indicate the start of the burst 430.

The sampling operation 400 enables the host system and the memory system to align the burst boundary 415 of the burst 430 with the correct phase of the multi-phase clock of the memory system. If there is a misalignment between the burst boundary 415 and the multi-phase clock, the memory system may identify more errors in the signal communicated over the CA lines. The sampling operation 400 may occur when the memory system transitions to normal operation (e.g., after exiting a sleep mode, after exiting a refresh mode).

As part of the sampling operation 400, and as shown in the upper portion of FIG. 4, a CA capture to DQ return mapping operation 405 (e.g., performed in accordance with the mapping table 205 and the clocking diagram 210 of FIG. 2) may include the memory system receiving a packet including a synchronization pattern 410. As an example, and as shown in FIG. 4, the synchronization pattern 410 may be an example of a signal communicated over one or more UIs. The synchronization pattern 410 may include first HHHHH logic states, followed by second HHHHH logic states, followed by first LLLLL logic states, followed by second LLLLL logic states. Said another way, during a first UI (denoted by ‘1’) HHHHH is sent across the individual lines of the CA channel, during a second unit interval (denoted by ‘2) HHHHH is sent across the individual lines of the CA channel, during a third UI (denoted by ‘3’) LLLLL is sent across the individual lines of the CA channel, and during a fourth UI (denoted by ‘4’) LLLLL is sent across the individual lines of the CA channel. In some examples, the synchronization pattern 410 is received via CA lines (e.g., a CA bus corresponding to CA [4:0]) between a memory system including the memory system (e.g., the memory system 110) and a host system including a controller (e.g., the host system 105).

As shown in the lower portion of FIG. 4, the sampling operation 400 may further include the memory system receiving, from the host system, the single-phase clock 215. Using the single-phase clock 215, and based on a configuration of the internal bridge, the memory system may identify a degree of alignment between the burst boundary 415 associated with the single-phase clock 215 and a phase of the multi-phase clock 220. As shown in FIG. 4, the degree of alignment corresponds to an edge (e.g., a rising edge or a falling edge) of the single-phase clock 215 being aligned with an edge (e.g., a rising edge or a falling edge) of at least one of the phases of the phase CK4_1 (e.g., a phase that is shifted 90 degrees relative to the zero-degree reference phase).

Based on the degree of alignment, the memory system may generate a data word 420 that is indicative of a state of synchronization between the single-phase clock 215 and the multi-phase clock 220. As an example, and to indicate the single-phase clock 215 is not synchronized (e.g., the single-phase clock 215 is not aligned with CK4_0, but rather CK4_1), the data word 420 may include LHLHLHLHLH logic states communicated across DQ [9:0] (e.g., during a single UI). The data word 420 may be based, at least in part, on a logic state 425 of a DQE input during the training (e.g., an H logic state of the DQE input 230 in accordance with the mapping table 205). The data word 420 may then be transmitted to the host system via DQ lines (e.g., a data bus including DQ [9:0]) between the memory system and the host system.

After receiving the data word 420 and based at least in part on the data word 420, the host system may determine that the single-phase clock 215 is aligned with CK4_1 (e.g., the phase that is shifted 90 degrees relative to the zero-degree reference phase). As part of a subsequent transmission, the host system may further implement a 90-degree offset (e.g., to enable the memory system to decode subsequent transmissions).

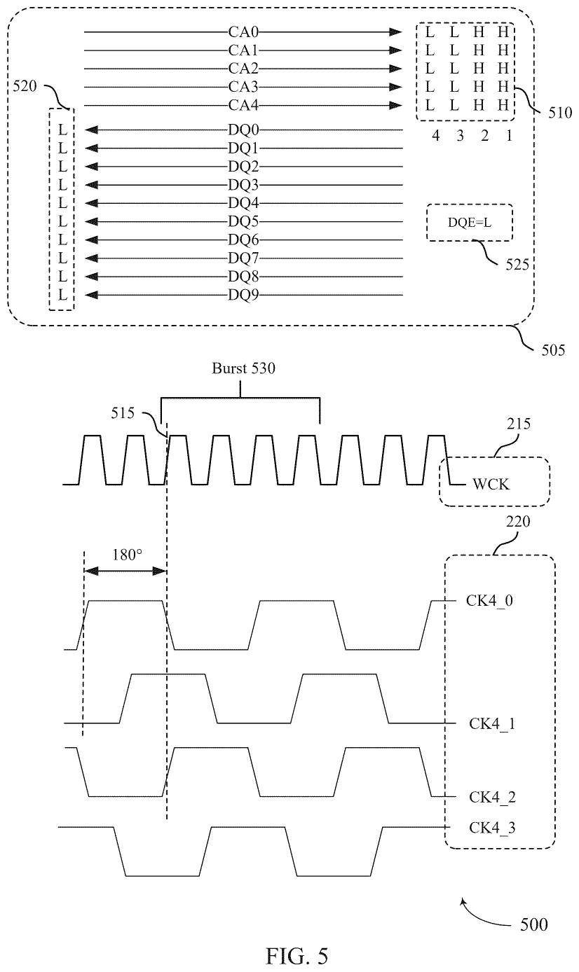

FIG. 5 shows an example of a sampling operation 500 that supports host-side alignment to a multi-phase internal clock of a memory system in accordance with examples as disclosed herein. The sampling operation 500 may be performed, at least in part, by an internal bridge of a memory system using aspects described in connection with FIG. 2 and elsewhere herein. The sampling operation 500 may be performed after the memory system enters a training mode (e.g., a command/address bus training mode).

The sampling operation 500 may be configured to align the memory system's (e.g., the DDR DRAM's) internal multi-phase clock (e.g., multi-phase clock 220, an internal CK4 clock of the DDR DRAM) with a burst boundary communicated over the CA lines by the host system. In some systems, the host system may issue commands in a burst 530 of one or more UIs. In some examples, the length of the burst 530 may be four UIs. However, other burst lengths are also possible (e.g., burst lengths of 1 UI, 2 UIs, 3 UIs, 4 UIs, 5 UIs, 6 UIs, 7 UIs, 8 UIs, 9 UIs, 10 UIs, 11 UIs, 12 UIs, 13 UIs, 14 UIs, 15 UIs, 16 UIs). The burst boundary 515 may indicate the start of the burst 530.

The sampling operation 500 enables the host system and the memory system to align the burst boundary 515 of the burst 530 with the correct phase of the multi-phase clock of the memory system. If there is a misalignment between the burst boundary 515 and the multi-phase clock, the memory system may identify more errors in the signal communicated over the C/A lines. The sampling operation 500 may occur when the memory system transitions to normal operation (e.g., after exiting a sleep mode, after exiting a refresh mode).

As part of the sampling operation 500, and as shown in the upper portion of FIG. 5, a CA capture to DQ return mapping operation 505 (e.g., performed in accordance with the mapping table 205 and the clocking diagram 210 of FIG. 2) may include the memory system receiving a packet including a synchronization pattern 510. As an example, and as shown in FIG. 5, the synchronization pattern 510 may be an example of a signal communicated over one or more UIs. The synchronization pattern 510 may include first HHHHH logic states, followed by second HHHHH logic states, followed by first LLLLL logic states, followed by second LLLLL logic states. Said another way, during a first UI (denoted by ‘1’) HHHHH is sent across the individual lines of the CA channel, during a second unit interval (denoted by ‘2) HHHHH is sent across the individual lines of the CA channel, during a third UI (denoted by ‘3’) LLLLL is sent across the individual lines of the CA channel, and during a fourth UI (denoted by ‘4’) LLLLL is sent across the individual lines of the CA channel. In some examples, the synchronization pattern 510 is received via command/address lines (e.g., a command/address bus corresponding to CA [4:0]) between a memory system including the memory system (e.g., the memory system 110) and a host system including a controller (e.g., the host system 105).

As shown in the lower portion of FIG. 5, the sampling operation 500 may further include the memory system receiving, from the host system, the single-phase clock 215. Using the single-phase clock 215, and based on a configuration of the internal bridge, the memory system may identify a degree of alignment between the burst boundary 515 associated with the single-phase clock 215 and a phase of the multi-phase clock 220. As shown in FIG. 5, the degree of alignment corresponds to an edge (e.g., a rising edge or a falling edge) of the single-phase clock 215 being aligned with an edge (e.g., a rising edge or a falling edge) of at least one of the phases of the phase CK4_2 (e.g., a phase that is shifted 180 degrees relative to the zero-degree reference phase).

Based on the degree of alignment, the memory system may generate a data word 520 that is indicative of a state of synchronization between the single-phase clock 215 and the multi-phase clock 220. As an example, and to indicate the single-phase clock 215 is not synchronized (e.g., the single-phase clock 215 is not aligned with CK4_0, but rather CK4_2), the data word 520 may include LLLLLLLLLL logic states communicated across DQ [9:0] (e.g., during a single UI). In some examples, the data word 520 may be based, at least in part, on a logic state 525 of a DQE input during the training (e.g., an L logic state of the DQE input 230 in accordance with the mapping table 205). The data word 520 may then be transmitted to the host system via data DQ lines (e.g., a data bus including DQ [9:0]) between the memory system and the host system.

After receiving the data word 520 and based at least in part on the data word 520, the host system may determine that the single-phase clock 215 is aligned with CK4_2 (e.g., the phase that is shifted 180 degrees relative to the zero-degree reference phase). As part of a subsequent transmission, the host system may further implement a 180-degree offset (e.g., to enable the memory system to decode subsequent transmissions)..

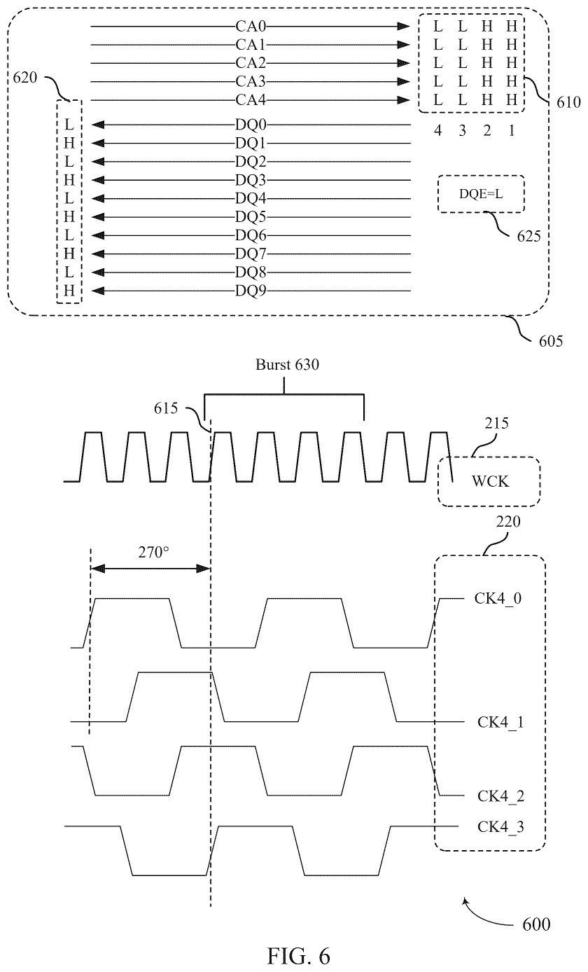

FIG. 6 shows an example of a sampling operation 600 that supports host-side alignment to a multi-phase internal clock of a memory system in accordance with examples as disclosed herein. The sampling operation 600 may be performed, at least in part, by an internal bridge of a memory system using aspects described in connection with FIG. 2 and elsewhere herein. The sampling operation 600 may be performed after the memory system enters a training mode (e.g., a command/address bus training mode).

The sampling operation 600 may be configured to align the memory system's (e.g., the DDR DRAM) with a burst boundary communicated over the CA lines by the host system. In some systems, the host system may issue commands in a burst 630 of one or more unit intervals (UIs). In some examples, the length of the burst 630 may be four UIs. However, other burst lengths are also possible (e.g., burst lengths of 1 UI, 2 UIs, 3 UIs, 4 UIs, 5 UIs, 6 UIs, 7 UIs, 8 UIs, 9 UIs, 10 UIs, 11 UIs, 12 UIs, 13 UIs, 14 UIs, 15 UIs, 16 UIs). The burst boundary 615 may indicate the start of the burst 630.

The sampling operation 600 enables the host system and the memory system to align the burst boundary 615 of the burst 630 with the correct phase of the multi-phase clock of the memory system. If there is a misalignment between the burst boundary 615 and the multi-phase clock, the memory system may identify more errors in the signal communicated over the CA lines. The sampling operation 600 may occur when the memory system transitions to normal operation (e.g., after exiting a sleep mode, after exiting a refresh mode).

As part of the sampling operation 600, and as shown in the upper portion of FIG. 6, a CA capture to DQ output return mapping operation 605 (e.g., performed in accordance with the mapping table 205 and the clocking diagram 210 of FIG. 2) may include the memory system receiving a packet including a synchronization pattern 610. As an example, and as shown in FIG. 6, the synchronization pattern 610 may be an example of a signal communicated over one or more unit intervals (sometimes referred to a UIs). The synchronization pattern 610 may include first HHHHH logic states, followed by second HHHHH logic states, followed by first LLLLL logic states, followed by second LLLLL logic states. Said another way, during a first UI (denoted by ‘1’) HHHHH is sent across the individual lines of the CA channel, during a second UI (denoted by ‘2) HHHHH is sent across the individual lines of the CA channel, during a third UI (denoted by ‘3’) LLLLL is sent across the individual lines of the CA channel, and during a fourth UI (denoted by ‘4’) LLLLL is sent across the individual lines of the CA channel. In some examples, the synchronization pattern 610 is received via CA lines (e.g., a CA bus corresponding to CA [4:0]) between a memory system including the memory system (e.g., the memory system 110) and a host system including a controller (e.g., the host system 105).

As shown in the lower portion of FIG. 6, the sampling operation 600 may further include the memory system receiving, from the host system, the single-phase clock 215. Using the single-phase clock 215, and based on a configuration of the internal bridge, the memory system may identify a degree of alignment between the burst boundary 615 associated with the single-phase clock 215 and a phase of the multi-phase clock 220. As shown in FIG. 6, the degree of alignment corresponds to an edge (e.g., a rising edge or a falling edge) of the single-phase clock 215 being aligned with an edge (e.g., a rising edge or a falling edge) of at least one of the phases of the phase CK4_3 (e.g., a phase that is shifted 270 degrees relative to the zero-degree reference phase).

Based on the degree of alignment, the memory system may generate a data word 620 that is indicative of a state of synchronization between the single-phase clock 215 and the multi-phase clock 220. As an example, and to indicate the single-phase clock 215 is not synchronized (e.g., the single-phase clock 215 is not aligned with CK4_0, but rather CK4_2), the data word 620 may include HLHLHLHLHL logic states communicated across DQ [9:0] (e.g., during a single UI). In some examples, the data word 620 may be based, at least in part, on a logic state 625 of a DQE input during the training (e.g., an L logic state of the DQE input 230 in accordance with the mapping table 205). The data word 620 may then be transmitted to the host system via DQ lines (e.g., a data bus including DQ [9:0]) between the memory system and the host system.

After receiving the data word 620 and based at least in part on the data word 620, the host system may determine that the single-phase clock 215 is aligned with CK4_3 (e.g., the phase that is shifted 270 degrees relative to the zero-degree reference phase). As part of a subsequent transmission, the host system may further implement a 270-degree offset (e.g., to enable the memory system to decode subsequent transmissions).

Although FIGS. 1 through 6 describe aspects of aligning a clock of a host system with a clock of a memory system that may include DDR memory, or more aspects of FIGS. 1 through 6 may be applied between to aligning a clock of host system with a memory system including another type of memory. As an example, and a for a memory system including NAND memory, one or more aspects of FIGS. 1 through 6 may be performed through an open NAND flash interface (e.g., an ONFI compliant interface) and not be limited to use of a command/address bus and/or a data bus.

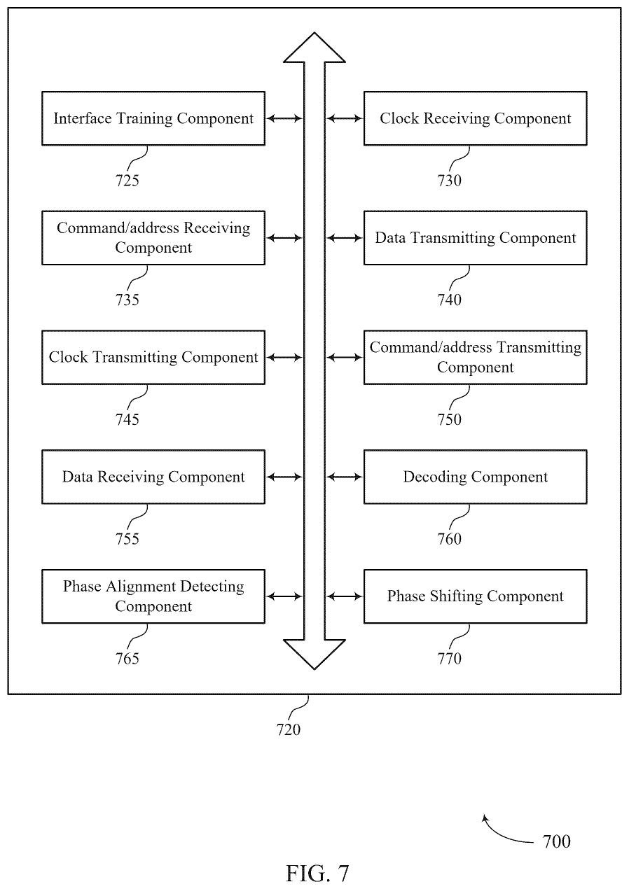

FIG. 7 shows a block diagram 700 of an apparatus 720 that supports host-side alignment to a multi-phase internal clock of a memory system in accordance with examples as disclosed herein. The apparatus 720 may be an example of aspects of an apparatus as described with reference to FIGS. 1 through 6. The apparatus 720, or various components thereof, may be an example of means for performing various aspects of host-side alignment to a multi-phase internal clock of a memory system as described herein. For example, the apparatus 720 may include an interface training component 725, a clock receiving component 730, a command/address receiving component 735, a data transmitting component 740, a clock transmitting component 745, a command/address transmitting component 750, a data receiving component 755, a decoding component 760, a phase alignment detecting component 765, a phase shifting component 770, or any combination thereof. Each of these components, or components of subcomponents thereof (e.g., one or more processors, one or more memories), may communicate, directly or indirectly, with one another (e.g., via one or more buses).

The interface training component 725 may be configured as or otherwise support a means for entering an interface training mode. The clock receiving component 730 may be configured as or otherwise support a means for receiving, while in the interface training mode, a single-phase clock. The command/address receiving component 735 may be configured as or otherwise support a means for receiving, while in the interface training mode, a first packet including a synchronization pattern that spans a multi-phase clock of the memory system. The data transmitting component 740 may be configured as or otherwise support a means for transmitting, while in the interface training mode, a data word indicative of a state of synchronization between the single-phase clock and the multi-phase clock. In some examples, the interface training component 725 may be configured as or otherwise support a means for exiting the interface training mode. In some examples, the command/address receiving component 735 may be configured as or otherwise support a means for receiving a second packet, where arrival of an initial subpacket of the second packet is synchronized with a zero-degree reference phase of the multi-phase clock.

In some examples, to support entering the interface training mode, the interface training component 725 may be configured as or otherwise support a means for entering a command address bus training mode.

In some examples, to support receiving the first packet and the second packet, the command/address receiving component 735 may be configured as or otherwise support a means for receiving the first packet and the second packet via command/address lines between the memory system and a host system.

In some examples, to support transmitting the data word, the data transmitting component 740 may be configured as or otherwise support a means for transmitting the data word via data lines between the memory system and a host system.

In some examples, the decoding component 760 may be configured as or otherwise support a means for identifying contents of the second packet based on a mapping between inputs received via command/address lines and outputs output via data lines, where outputting the second packet is based at least in part on identifying the contents.

In some examples, the mapping links values received during a first UI via a first command/address line with a second UI output on a first data line.

In some examples, the synchronization pattern in the first packet is configured to cause different values for the second packet based at least in part on a mapping between inputs received via command/address lines and outputs output via data lines and on a degree of alignment with the multi-phase clock.

In some examples, to support transmitting the data word, the data transmitting component 740 may be configured as or otherwise support a means for outputting HHHHHHHHH logic states across a bus of the memory system to indicate that the single-phase clock is aligned with the zero-degree reference phase.

In some examples, to support transmitting the data word, the data transmitting component 740 may be configured as or otherwise support a means for outputting LHLHLHLHLH logic states across a bus of the memory system to indicate that the single-phase clock is aligned with a phase of the multi-phase clock that is shifted 90 degrees relative to the zero-degree reference phase.

In some examples, to support transmitting the data word, the data transmitting component 740 may be configured as or otherwise support a means for outputting LLLLLLLLLL logic states across a bus of the memory system to indicate that the single-phase clock is aligned with a phase of the multi-phase clock that is shifted 180 degrees relative to the zero-degree reference phase.

In some examples, to support transmitting the data word, the data transmitting component 740 may be configured as or otherwise support a means for outputting HLHLHLHLHL logic states across a bus of the memory system to indicate that the single-phase clock is aligned with a phase of the multi-phase clock that is shifted 270 degrees relative to the zero-degree reference phase.

The clock transmitting component 745 may be configured as or otherwise support a means for transmitting a single-phase clock. The command/address transmitting component 750 may be configured as or otherwise support a means for transmitting a first packet that includes a synchronization pattern spanning a multi-phase clock of a memory system. The data receiving component 755 may be configured as or otherwise support a means for receiving a data word that is indicative of a state of synchronization between the single-phase clock and the multi-phase clock. In some examples, the command/address transmitting component 750 may be configured as or otherwise support a means for transmitting a second packet, where transmission of an initial subpacket of the second packet is synchronized with a zero-degree reference phase of the multi-phase clock based at least in part on the data word.

In some examples, to support transmitting the single-phase clock, the clock transmitting component 745 may be configured as or otherwise support a means for transmitting an individual signal that is used for clocking data buses and clocking command buses of the memory system.

In some examples, to support transmitting the first packet and the second packet, the command/address transmitting component 750 may be configured as or otherwise support a means for transmitting the first packet and the second packet via command/address lines between the memory system and the host system.

In some examples, to support receiving the data word, the data receiving component 755 may be configured as or otherwise support a means for receiving the data word via data lines between the memory system and the host system.

In some examples, to support transmitting the synchronization pattern, the command/address transmitting component 750 may be configured as or otherwise support a means for outputting first HHHHH logic states across a bus of the memory system. In some examples, to support transmitting the synchronization pattern, the command/address transmitting component 750 may be configured as or otherwise support a means for outputting second HHHHH logic states across the bus after outputting the first HHHHH logic states. In some examples, to support transmitting the synchronization pattern, the command/address transmitting component 750 may be configured as or otherwise support a means for outputting first LLLLL logic states across the bus after outputting the second HHHHH logic states. In some examples, to support transmitting the synchronization pattern, the command/address receiving component 735 may be configured as or otherwise support a means for outputting second LLLLL logic states across the bus after outputting the first LLLLL logic states.

In some examples, the phase alignment detecting component 765 may be configured as or otherwise support a means for determining, based at least in part on the data word, that the single-phase clock is aligned with the zero-degree reference phase. In some examples, the phase shifting component 770 may be configured as or otherwise support a means for determining that implementing an offset relative to the single-phase clock is equal to zero.

In some examples, the phase alignment detecting component 765 may be configured as or otherwise support a means for determining, based at least in part on the data word, that the single-phase clock is aligned with a phase of the multi-phase clock that is shifted 90 degrees relative to the zero-degree reference phase. In some examples, the phase shifting component 770 may be configured as or otherwise support a means for implementing a 90-degree offset as part of transmitting the second packet.

In some examples, the phase alignment detecting component 765 may be configured as or otherwise support a means for determining, based at least in part on the data word, that the single-phase clock is aligned with a phase of the multi-phase clock that is shifted 180 degrees relative to the zero-degree reference phase. In some examples, the phase shifting component 770 may be configured as or otherwise support a means for implementing an 180-degree offset as part of transmitting the second packet.

In some examples, the phase alignment detecting component 765 may be configured as or otherwise support a means for determining, based at least in part on the data word, that the single-phase clock is aligned with a phase of the multi-phase clock that is shifted 270 degrees relative to the zero-degree reference phase. In some examples, the phase shifting component 770 may be configured as or otherwise support a means for implementing a 270-degree offset as part of transmitting the second packet.

In some examples, the described functionality of the apparatus 720, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the apparatus 720, or various components thereof, may be implemented at least in part by instructions (e.g., stored in memory, non-transitory computer-readable medium) executable by such at least one processor.

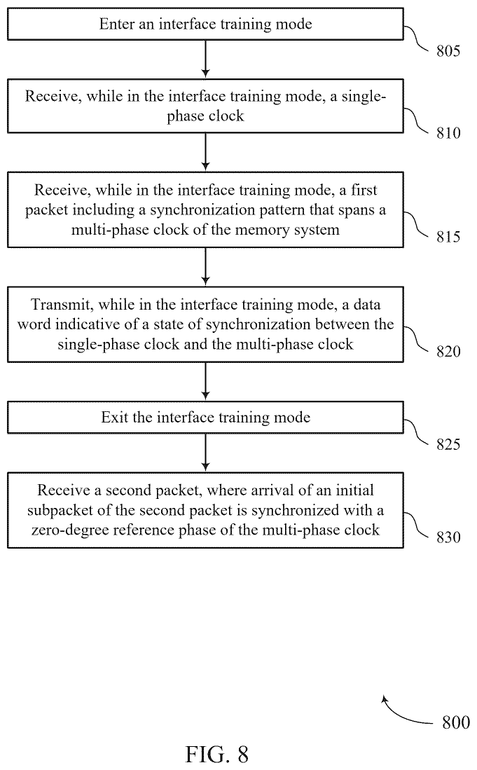

FIG. 8 shows a flowchart illustrating a method 800 that supports host-side alignment to a multi-phase internal clock of a memory system in accordance with examples as disclosed herein. The operations of method 800 may be implemented by a memory system or its components as described herein. For example, the operations of method 800 may be performed by a memory system as described with reference to FIGS. 1 through 7. In some examples, a memory system may execute a set of instructions to control the functional elements of the device to perform the described functions. Additionally, or alternatively, the memory system may perform aspects of the described functions using special-purpose hardware.

At 805, the method may include entering an interface training mode. In some examples, aspects of the operations of 805 may be performed by an interface training component 725 as described with reference to FIG. 7.

At 810, the method may include receiving, while in the interface training mode, a single-phase clock. In some examples, aspects of the operations of 810 may be performed by a clock receiving component 730 as described with reference to FIG. 7.

At 815, the method may include receiving, while in the interface training mode, a first packet including a synchronization pattern that spans a multi-phase clock of the memory system. In some examples, aspects of the operations of 815 may be performed by a command/address receiving component 735 as described with reference to FIG. 7.

At 820, the method may include transmitting, while in the interface training mode, a data word indicative of a state of synchronization between the single-phase clock and the multi-phase clock. In some examples, aspects of the operations of 820 may be performed by a data transmitting component 740 as described with reference to FIG. 7.

At 825, the method may include exiting the interface training mode. In some examples, aspects of the operations of 825 may be performed by an interface training component 725 as described with reference to FIG. 7.

At 830, the method may include receiving a second packet, where arrival of an initial subpacket of the second packet is synchronized with a zero-degree reference phase of the multi-phase clock. In some examples, aspects of the operations of 830 may be performed by a command/address receiving component 735 as described with reference to FIG. 7.

In some examples, an apparatus as described herein may perform a method or methods, such as the method 800. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for entering an interface training mode; receiving, while in the interface training mode, a single-phase clock; receiving, while in the interface training mode, a first packet including a synchronization pattern that spans a multi-phase clock of the memory system; transmitting, while in the interface training mode, a data word indicative of a state of synchronization between the single-phase clock and the multi-phase clock; exiting the interface training mode; and receiving a second packet, where arrival of an initial subpacket of the second packet is synchronized with a zero-degree reference phase of the multi-phase clock.

Aspect 2: The method, apparatus, or non-transitory computer-readable medium of aspect 1, where entering the interface training mode includes operations, features, circuitry, logic, means, or instructions, or any combination thereof for entering a command address bus training mode.

Aspect 3: The method, apparatus, or non-transitory computer-readable medium of any of aspects 1 through 2, where receiving the first packet and the second packet includes operations, features, circuitry, logic, means, or instructions, or any combination thereof for receiving the first packet and the second packet via command/address lines between the memory system and a host system.

Aspect 4: The method, apparatus, or non-transitory computer-readable medium of any of aspects 1 through 3, where transmitting the data word includes operations, features, circuitry, logic, means, or instructions, or any combination thereof for transmitting the data word via data lines between the memory system and a host system.

Aspect 5: The method, apparatus, or non-transitory computer-readable medium of any of aspects 1 through 4, further including operations, features, circuitry, logic, means, or instructions, or any combination thereof for identifying contents of the second packet based on a mapping between inputs received via command/address lines and outputs output via data lines, where outputting the second packet is based at least in part on identifying the contents.

Aspect 6: The method, apparatus, or non-transitory computer-readable medium of aspect 5, where the mapping links values received during a first unit interval via a first command/address line with a second unit interval output on a first data line.

Aspect 7: The method, apparatus, or non-transitory computer-readable medium of any of aspects 1 through 6, where the synchronization pattern in the first packet is configured to cause different values for the second packet based at least in part on a mapping between inputs received via command/address lines and outputs output via data lines and on a degree of alignment with the multi-phase clock.

Aspect 8: The method, apparatus, or non-transitory computer-readable medium of any of aspects 1 through 7, where transmitting the data word includes operations, features, circuitry, logic, means, or instructions, or any combination thereof for outputting HHHHHHHHH logic states across a bus of the memory system to indicate that the single-phase clock is aligned with the zero-degree reference phase.

Aspect 9: The method, apparatus, or non-transitory computer-readable medium of any of aspects 1 through 8, where transmitting the data word includes operations, features, circuitry, logic, means, or instructions, or any combination thereof for outputting LHLHLHLHLH logic states across a bus of the memory system to indicate that the single-phase clock is aligned with a phase of the multi-phase clock that is shifted 90 degrees relative to the zero-degree reference phase.

Aspect 10: The method, apparatus, or non-transitory computer-readable medium of any of aspects 1 through 9, where transmitting the data word includes operations, features, circuitry, logic, means, or instructions, or any combination thereof for outputting LLLLLLLLLL logic states across a bus of the memory system to indicate that the single-phase clock is aligned with a phase of the multi-phase clock that is shifted 180 degrees relative to the zero-degree reference phase.

Aspect 11: The method, apparatus, or non-transitory computer-readable medium of any of aspects 1 through 10, where transmitting the data word includes operations, features, circuitry, logic, means, or instructions, or any combination thereof for outputting HLHLHLHLHL logic states across a bus of the memory system to indicate that the single-phase clock is aligned with a phase of the multi-phase clock that is shifted 270 degrees relative to the zero-degree reference phase.

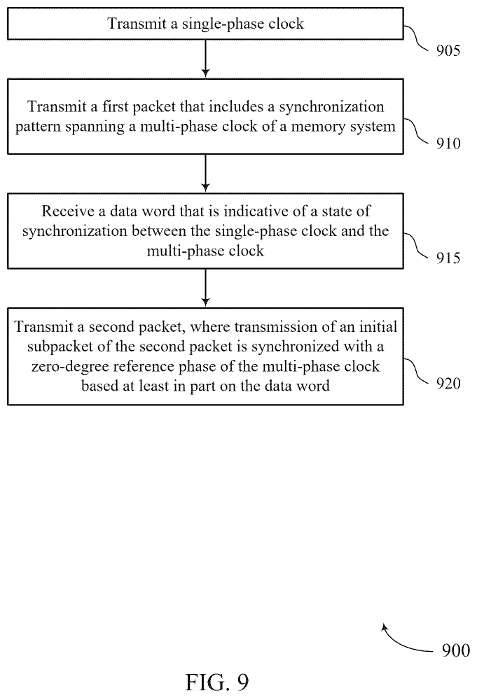

FIG. 9 shows a flowchart illustrating a method 900 that supports host-side alignment to a multi-phase internal clock of a memory system in accordance with examples as disclosed herein. The operations of method 900 may be implemented by a host system or its components as described herein. For example, the operations of method 900 may be performed by a host system as described with reference to FIGS. 1 through 7. In some examples, the host system may execute a set of instructions to control the functional elements of the device to perform the described functions. Additionally, or alternatively, the host system may perform aspects of the described functions using special-purpose hardware.

At 905, the method may include transmitting a single-phase clock. In some examples, aspects of the operations of 905 may be performed by a clock transmitting component 745 as described with reference to FIG. 7.

At 910, the method may include transmitting a first packet that includes a synchronization pattern spanning a multi-phase clock of a memory system. In some examples, aspects of the operations of 910 may be performed by a command/address transmitting component 750 as described with reference to FIG. 7.

At 915, the method may include receiving a data word that is indicative of a state of synchronization between the single-phase clock and the multi-phase clock. In some examples, aspects of the operations of 915 may be performed by a data receiving component 755 as described with reference to FIG. 7.

At 920, the method may include transmitting a second packet, where transmission of an initial subpacket of the second packet is synchronized with a zero-degree reference phase of the multi-phase clock based at least in part on the data word. In some examples, aspects of the operations of 920 may be performed by a command/address transmitting component 750 as described with reference to FIG. 7.

In some examples, an apparatus as described herein may perform a method or methods, such as the method 900. The apparatus may include features, circuitry, logic, means, or instructions (e.g., a non-transitory computer-readable medium storing instructions executable by a processor), or any combination thereof for performing the following aspects of the present disclosure:

Aspect 12: A method, apparatus, or non-transitory computer-readable medium including operations, features, circuitry, logic, means, or instructions, or any combination thereof for transmitting a single-phase clock; transmitting a first packet that includes a synchronization pattern spanning a multi-phase clock of a memory system; receiving a data word that is indicative of a state of synchronization between the single-phase clock and the multi-phase clock; and transmitting a second packet, where transmission of an initial subpacket of the second packet is synchronized with a zero-degree reference phase of the multi-phase clock based at least in part on the data word.

Aspect 13: The method, apparatus, or non-transitory computer-readable medium of aspect 12, where transmitting the single-phase clock includes operations, features, circuitry, logic, means, or instructions, or any combination thereof for transmitting an individual signal that is used for clocking data buses and clocking command buses of the memory system.

Aspect 14: The method, apparatus, or non-transitory computer-readable medium of any of aspects 12 through 13, where transmitting the first packet and the second packet includes operations, features, circuitry, logic, means, or instructions, or any combination thereof for transmitting the first packet and the second packet via command/address lines between the memory system and the host system.

Aspect 15: The method, apparatus, or non-transitory computer-readable medium of any of aspects 12 through 14, where receiving the data word includes operations, features, circuitry, logic, means, or instructions, or any combination thereof for receiving the data word via data lines between the memory system and the host system.

Aspect 16: The method, apparatus, or non-transitory computer-readable medium of any of aspects 12 through 15, where transmitting the synchronization pattern includes operations, features, circuitry, logic, means, or instructions, or any combination thereof for outputting first HHHHH logic states across a bus of the memory system; outputting second HHHHH logic states across the bus after outputting the first HHHHH logic states; outputting first LLLLL logic states across the bus after outputting the second HHHHH logic states; and outputting second LLLLL logic states across the bus after outputting the first LLLLL logic states.

Aspect 17: The method, apparatus, or non-transitory computer-readable medium of any of aspects 12 through 16, further including operations, features, circuitry, logic, means, or instructions, or any combination thereof for determining, based at least in part on the data word, that the single-phase clock is aligned with the zero-degree reference phase and determining that implementing an offset relative to the single-phase clock is equal to zero.

Aspect 18: The method, apparatus, or non-transitory computer-readable medium of any of aspects 12 through 17, further including operations, features, circuitry, logic, means, or instructions, or any combination thereof for determining, based at least in part on the data word, that the single-phase clock is aligned with a phase of the multi-phase clock that is shifted 90 degrees relative to the zero-degree reference phase and implementing a 90-degree offset as part of transmitting the second packet.

Aspect 19: The method, apparatus, or non-transitory computer-readable medium of any of aspects 12 through 18, further including operations, features, circuitry, logic, means, or instructions, or any combination thereof for determining, based at least in part on the data word, that the single-phase clock is aligned with a phase of the multi-phase clock that is shifted 180 degrees relative to the zero-degree reference phase and implementing an180-degree offset as part of transmitting the second packet.

Aspect 20: The method, apparatus, or non-transitory computer-readable medium of any of aspects 12 through 19, further including operations, features, circuitry, logic, means, or instructions, or any combination thereof for determining, based at least in part on the data word, that the single-phase clock is aligned with a phase of the multi-phase clock that is shifted 270 degrees relative to the zero-degree reference phase and implementing a 270-degree offset as part of transmitting the second packet.

It should be noted that the aspects described herein describe possible examples, and that the operations and the steps may be rearranged or otherwise modified and that other examples are possible. Further, portions from two or more of the methods may be combined.

An apparatus is described. The following provides an overview of aspects of the apparatus as described herein:

Aspect 21: An apparatus, including: a memory system, including: double data rate random access memory; and a host system including logic integrated circuitry that is configured to: transmit a synchronization pattern to the double data rate random access memory; determine a command start point based at least in part on a command/address capture to data input/output return mapping; and transmit a command packet to the double data rate random access memory using the command start point.

Aspect 22: The apparatus of aspect 21, further including: a command/address bus having a 5-bit width; and a data input/output bus having a 10-bit width.

Aspect 23: The apparatus of aspect 22, where the logic integrated circuitry is further configured to: generate an individual clock that is used for clocking the command/address bus and the data input/output bus.

Aspect 24: The apparatus of any of aspects 21 through 23, where the double data rate random access memory includes: command/address sampling integrated circuitry that is used to generate the command/address capture to data input/output return mapping.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method at a memory system, comprising:
entering an interface training mode;
receiving, while in the interface training mode, a single-phase clock;
receiving, while in the interface training mode, a first packet comprising a synchronization pattern that spans a multi-phase clock of the memory system;
transmitting, while in the interface training mode, a data word indicative of a state of synchronization between the single-phase clock and the multi-phase clock;
exiting the interface training mode; and
receiving a second packet, wherein arrival of an initial subpacket of the second packet is synchronized with a zero-degree reference phase of the multi-phase clock.

2. The method of claim 1, wherein entering the interface training mode comprises:
entering a command address bus training mode.

3. The method of claim 1, wherein receiving the first packet and the second packet comprises:
receiving the first packet and the second packet via command/address lines between the memory system and a host system.

4. The method of claim 1, wherein transmitting the data word comprises:
transmitting the data word via data lines between the memory system and a host system.

5. The method of claim 1, further comprising:
identifying contents of the second packet based on a mapping between inputs received via command/address lines and outputs output via data lines, wherein outputting the second packet is based at least in part on identifying the contents.

6. The method of claim 5, wherein the mapping links values received during a first unit interval via a first command/address line with a second unit interval output on a first data line.

7. The method of claim 1, wherein the synchronization pattern in the first packet is configured to cause different values for the second packet based at least in part on a mapping between inputs received via command/address lines and outputs output via data lines and on a degree of alignment with the multi-phase clock.

8. The method of claim 1, wherein transmitting the data word comprises:
outputting HHHHHHHHH logic states across a bus of the memory system to indicate that the single-phase clock is aligned with the zero-degree reference phase.

9. The method of claim 1, wherein transmitting the data word comprises:
outputting LHLHLHLHLH logic states across a bus of the memory system to indicate that the single-phase clock is aligned with a phase of the multi-phase clock that is shifted 90 degrees relative to the zero-degree reference phase.

10. The method of claim 1, wherein transmitting the data word comprises:
outputting LLLLLLLLLL logic states across a bus of the memory system to indicate that the single-phase clock is aligned with a phase of the multi-phase clock that is shifted 180 degrees relative to the zero-degree reference phase.

11. The method of claim 1, wherein transmitting the data word comprises:
outputting HLHLHLHLHL logic states across a bus of the memory system to indicate that the single-phase clock is aligned with a phase of the multi-phase clock that is shifted 270 degrees relative to the zero-degree reference phase.

12. A method at a host system, comprising:
transmitting a single-phase clock;
transmitting a first packet that comprises a synchronization pattern spanning a multi-phase clock of a memory system;
receiving a data word that is indicative of a state of synchronization between the single-phase clock and the multi-phase clock; and
transmitting a second packet, wherein transmission of an initial subpacket of the second packet is synchronized with a zero-degree reference phase of the multi-phase clock based at least in part on the data word.

13. The method of claim 12, wherein transmitting the single-phase clock comprises:
transmitting an individual signal that is used for clocking data buses and clocking command buses of the memory system.

14. The method of claim 12, wherein transmitting the first packet and the second packet comprises:
transmitting the first packet and the second packet via command/address lines between the memory system and the host system.

15. The method of claim 12, wherein receiving the data word comprises:
receiving the data word via data lines between the memory system and the host system.

16. The method of claim 12, wherein transmitting the synchronization pattern comprises:
outputting first HHHHH logic states across a bus of the memory system;
outputting second HHHHH logic states across the bus after outputting the first HHHHH logic states;
outputting first LLLLL logic states across the bus after outputting the second HHHHH logic states; and
outputting second LLLLL logic states across the bus after outputting the first LLLLL logic states.

17. The method of claim 12, further comprising:
determining, based at least in part on the data word, that the single-phase clock is aligned with the zero-degree reference phase; and
determining that implementing an offset relative to the single-phase clock is equal to zero.

18. The method of claim 12, further comprising:
determining, based at least in part on the data word, that the single-phase clock is aligned with a phase of the multi-phase clock that is shifted 90 degrees relative to the zero-degree reference phase; and
implementing a 90-degree offset as part of transmitting the second packet.

19. The method of claim 12, further comprising:
determining, based at least in part on the data word, that the single-phase clock is aligned with a phase of the multi-phase clock that is shifted 180 degrees relative to the zero-degree reference phase; and
implementing an180-degree offset as part of transmitting the second packet.

20. The method of claim 12, further comprising:
determining, based at least in part on the data word, that the single-phase clock is aligned with a phase of the multi-phase clock that is shifted 270 degrees relative to the zero-degree reference phase; and
implementing a 270-degree offset as part of transmitting the second packet.

21. An apparatus, comprising:
a memory system, comprising:
double data rate random access memory; and
a host system comprising logic integrated circuitry that is configured to:
transmit a synchronization pattern to the double data rate random access memory;
determine a command start point based at least in part on a command/address capture to data input/output return mapping; and
transmit a command packet to the double data rate random access memory using the command start point.

22. The apparatus of claim 21, further comprising:
a command/address bus having a 5-bit width; and
a data input/output bus having a 10-bit width.

23. The apparatus of claim 22, wherein the logic integrated circuitry is further configured to:
generate an individual clock that is used for clocking the command/address bus and the data input/output bus.

24. The apparatus of claim 21, wherein the double data rate random access memory comprises:
command/address sampling integrated circuitry that is used to generate the command/address capture to the data input/output return mapping.
